(19) United States
(12) Patent Application Publication
(10) Pub. No.: US 2026/0370154 A1
(43) Pub. Date: Nov. 19, 2026

(54) POWER CONVERSION DEVICE

(71) Applicant: TMEIC Corporation, Tokyo (JP)

(72) Inventor: Tsubasa SASAKI, Chuo-ku (JP)

(73) Assignee: TMEIC Corporation, Tokyo (JP)

(21) Appl. No.: 19/136,713

(22) PCT Filed: Nov. 9, 2023
(86) PCT No.: PCT/JP2023/040386

§ 371 Date: Jun. 6, 2025

(51) Int. Cl. H02M 7/00; H10D 80/20; H10D 80/30; H10W 76/132

(52) U.S. Cl. CPC H02M 7/003; H10D 80/215; H10D 80/30; H10W 76/132

(57) ABSTRACT

Semiconductor modules are arranged on a first surface of a substrate so as to be aligned along a first direction orthogonal to a vertical direction. At least one first capacitor is arranged on the side of a second surface of the substrate so that the extending direction of a cylindrical portion is a second direction orthogonal to the vertical direction and the first direction. At least one second capacitor is arranged on the side of the second surface so that the extending direction of the cylindrical portion is the second direction and its electrode terminals are located opposite the electrode terminals of the at least one first capacitor. In a plan view seen in the first direction, the at least one first capacitor and the at least one second capacitor are arranged so that their cylindrical portions partially overlap each other in the vertical direction and the second direction.

### TECHNICAL FIELD

The present disclosure relates to a power conversion device.

### BACKGROUND ART

Japanese Patent Laying-Open No. 2016-139702 (PTL 1) discloses an attachment structure of a capacitor in a power conversion device. The power conversion device includes a plurality of capacitors connected in parallel, a first conductive plate and a second conductive plate to which electrodes of the capacitors are connected, and a semiconductor module connected to the first conductive plate or the second conductive plate. The first conductive plate and the second conductive plate are stacked with interposition of an insulating plate and form a stack.

The first conductive plate and the second conductive plate each include a connection portion to which the semiconductor module is connected. The plurality of capacitors are alternately provided on one surface and the other surface of the stack. The capacitors provided adjacent to each other on the first conductive plate side and the second conductive plate side with interposition of the stack are arranged so that pairs of electrodes are opposite each other in a direction in which the capacitors are adjacent to each other.

### CITATION LIST

### Patent Literature

PTL 1: Japanese Patent Laying-Open No. 2016-139702

### SUMMARY OF INVENTION

### Technical Problem

The above-described attachment structure of the capacitors enables it to reduce the difference between the distance between the capacitor provided on the first conductive plate and the semiconductor module and the distance between the capacitor provided on the second conductive plate and the semiconductor module. Accordingly, imbalance in the current share among the capacitors can be hindered.

However, since the capacitor on the first conductive plate side and the capacitor on the second conductive plate side are arranged side by side along the horizontal direction, there is a concern that the dimension of the power conversion device in the horizontal direction may be lengthened and the area occupied by the power conversion device may be increased.

Thus, a main object of the present disclosure is to provide a power conversion device that enables it to reduce variation in the distance between a capacitor and a semiconductor module among a plurality of capacitors without increasing the area occupied by the power conversion device.

### Solution to Problem

A power conversion device according to an aspect of the present disclosure includes a plurality of capacitors, a plurality of semiconductor modules, and a substrate. The plurality of capacitors are electrically connected in parallel. The plurality of semiconductor modules are electrically connected to the plurality of capacitors. The substrate includes a first surface on which the plurality of semiconductor modules are mounted, and a second surface being opposite the first surface. The plurality of semiconductor modules are arranged on the first surface of the substrate so as to be aligned along a first direction orthogonal to a vertical direction of the power conversion device. Each of the plurality of capacitors includes a cylindrical portion, and first and second electrode terminals arranged in a first end portion of the cylindrical portion in an extending direction of the cylindrical portion. The plurality of capacitors include at least one first capacitor and at least one second capacitor. The at least one first capacitor is arranged on a side of the second surface of the substrate so that the extending direction of the cylindrical portion is a second direction orthogonal to the vertical direction and the first direction. The at least one second capacitor is arranged on the side of the second surface of the substrate so that the extending direction of the cylindrical portion is the second direction and the first and second electrode terminals of the at least one second capacitor are located opposite the first and second electrode terminals of the at least one first capacitor in the second direction. In a plan view seen in the first direction, the at least one first capacitor and the at least one second capacitor are arranged so that the cylindrical portions of the at least one first capacitor and the at least one second capacitor partially overlap each other in the vertical direction and the second direction.

### Advantageous Effects of Invention

The present disclosure can provide a power conversion device that enables it to reduce variation in the distance between a capacitor and a semiconductor module among a plurality of capacitors without increasing the area occupied by the power conversion device.

### BRIEF DESCRIPTION OF DRAWINGS

FIG. 1 is a block diagram illustrating a circuit configuration of a power conversion device according to an embodiment.

FIG. 2 is a diagram schematically illustrating a connection relation between the power conversion device and a capacitor circuit.

FIG. 3 is an external perspective view of the power conversion device according to the present embodiment.

FIG. 4 is an exploded perspective view of the power conversion device.

FIG. 5 is a front view of the power conversion device.

FIG. 6 is a top view of the power conversion device.

FIG. 7 is a side view of the power conversion device seen in the direction of arrow VII shown in FIG. 6.

FIG. 8 is a side view of the power conversion device seen in the direction of arrow VIII shown in FIG. 6.

FIG. 9 is an external perspective view of a power conversion device according to a comparative example.

FIG. 10 is an external perspective view of the power conversion device according to the comparative example.

### DESCRIPTION OF EMBODIMENTS

Embodiments of the present disclosure are described in detail below with reference to the drawings. Hereinafter, the same or corresponding portions in the drawings are denoted by the same reference characters and are not described repeatedly in principle.

### Circuit Configuration of Power Conversion Device

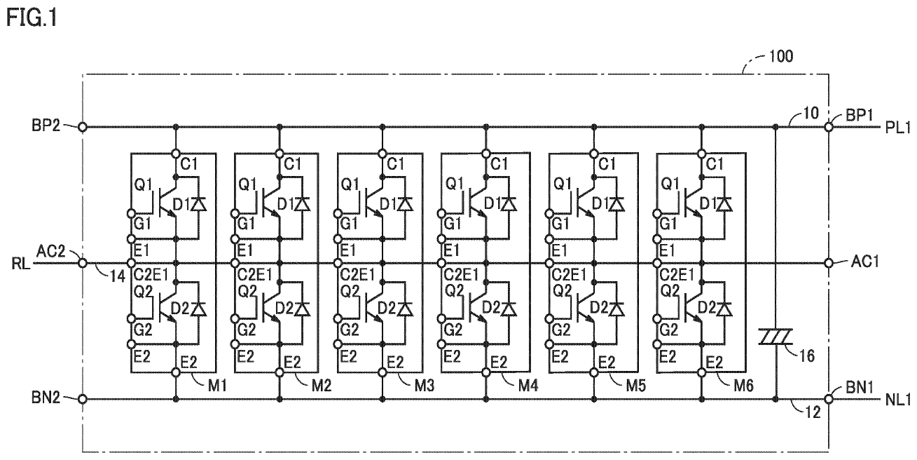

FIG. 1 is a block diagram illustrating a circuit configuration of a power conversion device according to an embodiment of the present disclosure. FIG. 1 illustrates a configuration example of a converter using power conversion device 100. The converter receives an R-phase voltage VR from an alternating current (AC) power supply, which is not illustrated, via an R-phase line RL. The converter is configured to convert R-phase voltage VR into a direct current (DC) voltage and output the DC voltage between DC buses PL1 and NL1.

As illustrated in FIG. 1, power conversion device 100 includes AC terminals AC1 and AC2, positive electrode DC terminals BP1 and BP2, and negative electrode DC terminals BN1 and BN2.

AC terminals AC1 and AC2 each receive an AC power. In the example of a converter, AC terminal AC2 is connected to the R-phase line and receives R-phase voltage VR from the AC power supply. Although not illustrated, in the example of an inverter, AC terminal AC1 is connected to a U-phase line and outputs a U-phase voltage VU.

Positive electrode DC terminals BP1 and BP2 are connected to DC positive bus PL1. Negative electrode DC terminals BN1 and BN2 are connected to DC negative bus NL1. In the example of a converter, positive electrode DC terminal BP1 is connected to DC positive bus PL1 and negative electrode DC terminal BN1 is connected to DC negative bus NL1. In the example of an inverter, positive electrode DC terminal BP2 is connected to DC positive bus PL1 and negative electrode DC terminal BN2 is connected to DC negative bus NL1.

Power conversion device 100 includes DC lines 10 and 12, an AC line 14, a plurality of semiconductor modules M1 to M6, and a capacitor circuit 16.

DC line 10 is connected between positive electrode DC terminal BP1 and positive electrode DC terminal BP2. DC line 12 is connected between negative electrode DC terminal BN1 and negative electrode DC terminal BN2. AC line 14 is connected between AC terminal AC1 and AC terminal AC2.

The plurality of semiconductor modules M1 to M6 are connected in parallel to each other between DC line 10 and DC line 12. Hereinafter, semiconductor modules M1 to M6 may be collectively referred to as semiconductor modules M. The number of semiconductor modules M is not limited to six but can be changed to any desired number, which includes one.

Semiconductor module M includes semiconductor switching elements Q1 and Q2, diodes D1 and D2, a collector terminal C1, an emitter terminal E2, a collector-emitter terminal C2E1, and control terminals G1, G2, E1, and E2. Each of semiconductor switching elements Q1 and Q2 is, for example, an insulated gate bipolar transistor (IGBT). The collector of IGBT Q1 is connected to collector terminal C1, and the emitter thereof is connected to the collector of IGBT Q2, control terminal E1, and collector-emitter terminal C2E1. The gate of IGBT Q1 is connected to control terminal G1. The emitter of IGBT Q2 is connected to emitter terminal E2 and control terminal E2, and the gate thereof is connected to control terminal G2. Diodes D1 and D2 are connected in anti-parallel to IGBTs Q1 and Q2, respectively.

Collector terminal C1 of semiconductor module M is connected to DC line 10 and emitter terminal E2 is connected to DC line 12. Collector-emitter terminal C2E1 of semiconductor module M is connected to AC line 14. Collector terminal C1 corresponds to an example of the “first main electrode terminal”, and emitter terminal E2 corresponds to an example of the “second main electrode terminal”.

The positive electrode of capacitor circuit 16 is connected to DC line 10 and the negative electrode thereof is connected to DC line 12. Capacitor circuit 16 includes a plurality of capacitors 40 connected in parallel as described later.

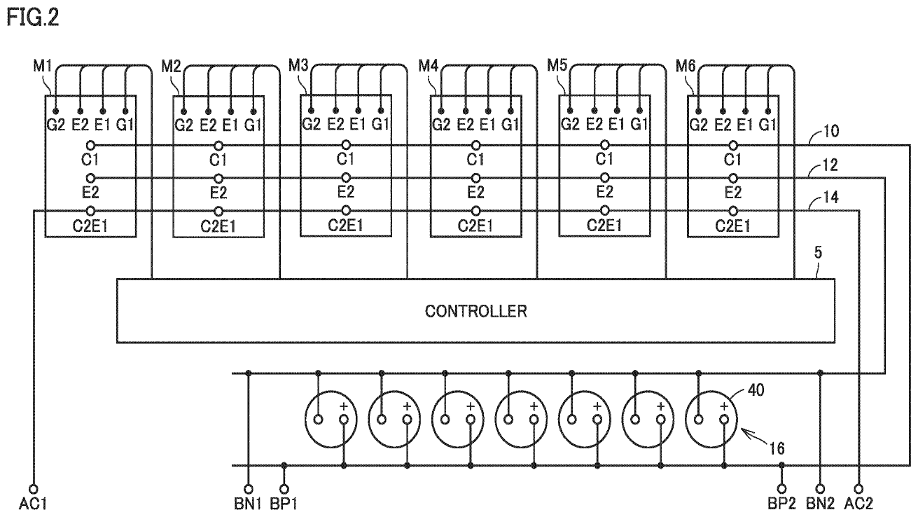

FIG. 2 is a diagram schematically illustrating a connection relation between power conversion device 100 and capacitor circuit 16. As illustrated in FIG. 2, control terminals G1, G2, E1, and E2 of each semiconductor module M are connected to a controller 5. Collector terminal C1 of each semiconductor module M is connected to DC line 10, emitter terminal E2 thereof is connected to DC line 12, and collector-emitter terminal C2E1 thereof is connected to AC line 14.

The plurality of capacitors 40 constituting capacitor circuit 16 are connected in parallel between DC line 10 and DC line 12. A positive electrode terminal of each capacitor 40 is connected to DC line 10 and a negative electrode terminal thereof is connected to DC line 12. The number of capacitors 40 can be changed as desired.

Positive electrode DC terminals BP1 and BP2 are led to the outside of power conversion device 100 from DC line 10. Negative electrode DC terminals BN1 and BN2 are led to the outside of power conversion device 100 from DC line 12. AC terminals AC1 and AC2 are led to the outside of power conversion device 100 from AC line 14.

### Mounting Structure of Power Conversion Device

A mounting structure of the power conversion device according to the present embodiment is described next. First, a mounting structure of a power conversion device according to a comparative example of the present embodiment and problems of the mounting structure are described.

### Comparative Example

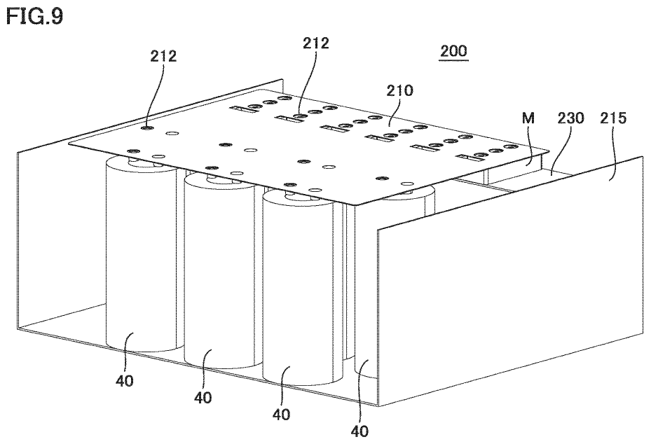

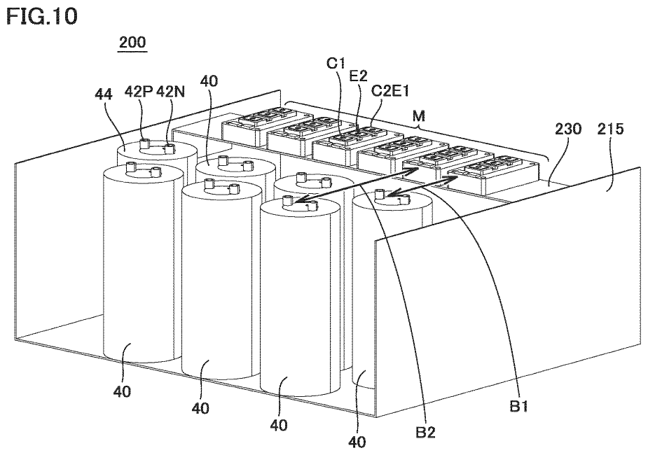

FIGS. 9 and 10 are external perspective views of the power conversion device according to the comparative example. As illustrated in FIG. 9, power conversion device 200 according to the comparative example has a rectangular parallelepiped shape. Power conversion device 200 is configured by connecting a plurality of semiconductor modules M and a plurality of capacitors 40 to a stack 210.

Stack 210 has a shape like a rectangular plate. Stack 210 is configured by alternately stacking a plurality of insulating plates on a plurality of conductive plates. Specifically, stack 210 includes a first conductive plate on which a DC line 10 is formed, a second conductive plate on which a DC line 12 is formed, a third conductive plate on which an AC line 14 is formed, and four insulating plates. These are stacked, from the lower side in the vertical direction, in the order of the insulating plate, the second conductive plate, the insulating plate, the first conductive plate, the insulating plate, the third conductive plate, and the insulating plate.

A plurality of through holes 212 penetrating in the thickness direction are formed in predetermined positions of stack 210. Connecting bolts are inserted in the plurality of through holes 212. By the connecting bolts, AC line 14, DC line 10, and DC line 12 can be electrically connected to the plurality of semiconductor modules M and the plurality of capacitors 40 in predetermined positions.

FIG. 10 illustrates power conversion device 200 shown in FIG. 9, from which stack 210 is removed. As illustrated in FIG. 10, the plurality of semiconductor modules M and the plurality of capacitors 40 are accommodated in a housing 215 having a rectangular parallelepiped shape.

The plurality of capacitors 40 constitute capacitor circuit 16 illustrated in FIGS. 1 and 2. The plurality of capacitors 40 are arranged side by side so as to stand on a bottom surface of housing 215. For example, the plurality of capacitors 40 are arranged in a staggered manner. That is, the plurality of capacitors 40 are arranged at equal intervals in two rows in the length direction of a substrate 230 and are alternately arranged in the opposite rows.

Capacitor 40 includes a cylindrical portion 44, and a positive electrode terminal 42P and a negative electrode terminal 42N that are provided in a first end portion of cylindrical portion 44 in the extending direction of cylindrical portion 44, i.e. the direction in which cylindrical portion 44 extends. Positive electrode terminal 42P and negative electrode terminal 42N correspond to examples of the “first electrode terminal” and the “second electrode terminal”, respectively. Capacitor 40 is mounted on stack 210 by electrically connecting positive electrode terminal 42P and negative electrode terminal 42N to stack 210 using the connecting bolts.

Substrate 230 is attached to an upper portion of housing 215 in parallel to the bottom surface of housing 215. Substrate 230 has a shape like a rectangular flat plate. The plurality of semiconductor modules M are arranged side by side on a surface of substrate 230 in the length direction. Semiconductor module M includes a resin formed in a rectangular shape, and a collector terminal C1, an emitter terminal E2, and a collector-emitter terminal C2E1 that are arranged so as to project from a surface of the resin in parallel to each other. Semiconductor module M is mounted on stack 210 by electrically connecting collector terminal E1, emitter terminal E2, and collector-emitter terminal C2E1 to stack 210 using the connecting bolts.

When seen from an upper surface of housing 215, the plurality of semiconductor modules M and the plurality of capacitors 40 are arranged side by side in the horizontal direction. In addition, the plurality of semiconductor modules M and the plurality of capacitors 40 are arranged so that the positions of collector terminal E1, emitter terminal E2, and collector-emitter terminal C2E1 of semiconductor module M in housing 215 in the vertical direction are on a level with the positions of positive electrode terminal 42P and negative electrode terminal 42N of capacitor 40 in the vertical direction. Thus, the plurality of semiconductor modules M and the plurality of capacitors 40 can be electrically connected to each other via stack 210.

However, since the plurality of semiconductor modules M and the plurality of capacitors 40 are arranged side by side in the horizontal direction, there is a concern that the area occupied by power conversion device 200 may be increased as the number of capacitors 40 becomes larger.

Further, since the plurality of capacitors 40 are arranged in two rows, variation in the distance between capacitor 40 and semiconductor module M occurs among the plurality of capacitors 40. Arrows B1 in FIG. 10 indicate a distance between capacitor 40 in the row relatively closer to semiconductor module M and semiconductor module M. Arrows B2 in FIG. 10 indicate a distance between capacitor 40 in the row relatively farther from semiconductor module M and semiconductor module M. The length between arrows B2 is shorter than the length between arrows B1.

Here, the distance between capacitor 40 and semiconductor module M is proportional to the inductance of a current path formed between capacitor 40 and semiconductor module M. Accordingly, as the distance between capacitor 40 and semiconductor module M is lengthened, the inductance of the current path increases. The increase in the inductance of the current path causes augmentation of power loss that occurs in the power conversion device.

Thus, power conversion device 200 according to the comparative example has a problem that the area occupied by the power conversion device increases with the number of capacitors 40 constituting capacitor circuit 16. In addition, since the distance between capacitor 40 and semiconductor module M varies among the plurality of capacitors 40, there is a problem that the inductance of the current path varies among the plurality of capacitors 40. It is a concern that the variation in inductance among the plurality of capacitors 40 may adversely affect the characteristics of power conversion device 200. The present embodiment provides a novel mounting structure that enables it to solve these problems.

### Mounting Structure of Power Conversion Device According to Present Embodiment

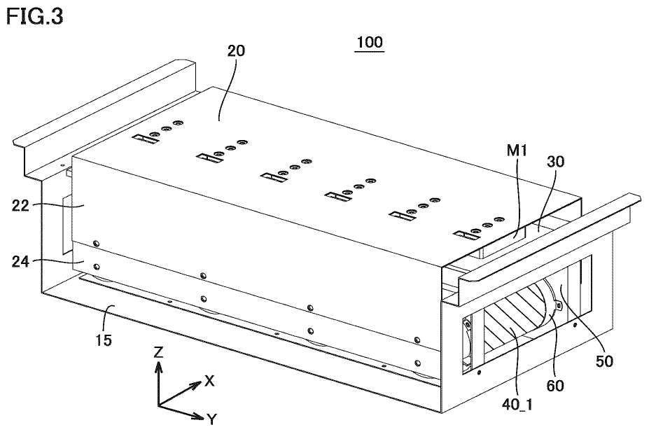

FIG. 3 is an external perspective view of power conversion device 100 according to the present embodiment. The perspective view shown in FIG. 3 is a perspective view of power conversion device 100 seen from the front side.

As illustrated in FIG. 3, power conversion device 100 has a rectangular parallelepiped shape. In the description below, when power conversion device 100 is seen from the front, the left-right direction is defined as an X direction, the front-rear direction is defined as a Y direction, and the vertical direction is defined as a Z direction. The X direction corresponds to the “second direction” and the Y direction corresponds to the “first direction”.

Power conversion device 100 is configured by connecting the plurality of semiconductor modules M and the plurality of capacitors 40 to a stack 20. Power conversion device 100 is different from power conversion device 200 according to the comparative example illustrated in FIGS. 9 and 10 in the arrangement of the plurality of capacitors 40 and the shape of stack 20.

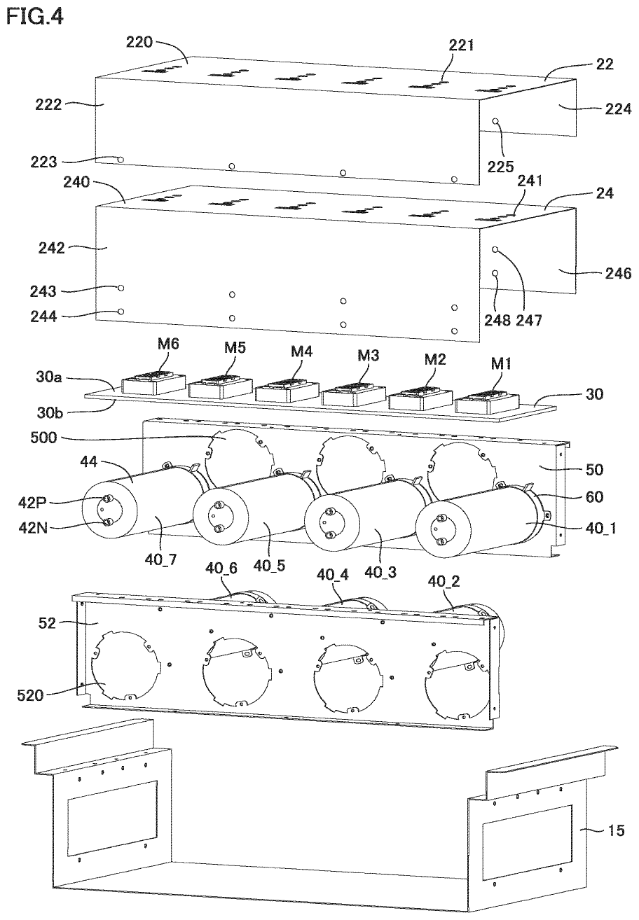

FIG. 4 is an exploded perspective view of power conversion device 100 illustrated in FIG. 3. As illustrated in FIG. 4, power conversion device 100 includes a first conductive plate 22, a second conductive plate 24, a substrate 30, the plurality of semiconductor modules M1 to M6, the plurality of capacitors 40_1 to 40_7, a first fixing plate 50, a second fixing plate 52, and a housing 15. First conductive plate 22, second conductive plate 24, substrate 30, the plurality of semiconductor modules M1 to M6, the plurality of capacitors 40_1 to 40_7, first fixing plate 50, and second fixing plate 52 are accommodated in housing 15.

Substrate 30 is attached to an upper portion of housing 15 in parallel to a bottom surface of housing 15. Substrate 30 has a shape like a rectangular flat plate. Substrate 30 includes a first surface 30a and a second surface 30b being opposite first surface 30a. Second surface 30b faces the bottom surface of housing 15.

The plurality of semiconductor modules M1 to M6 are mounted on first surface 30a of substrate 30. The plurality of semiconductor modules M1 to M6 are arranged side by side on first surface 30a of substrate 30 in the Y direction.

The plurality of capacitors 40_1 to 40_7 constitute capacitor circuit 16. The plurality of capacitors 40_1 to 40_7 are mounted on the second surface 30b side of substrate 30.

Specifically, the plurality of capacitors 40_1 to 40_7 are classified into first capacitors 40_1, 40_3, 40_5, and 40_7, and second capacitors 40_2, 40_4, and _6. When the number of capacitors 40 constituting capacitor circuit 16 is an even number, the number of first capacitors and the number of second capacitors are preferably made the same. When the number of capacitors 40 constituting capacitor circuit 16 is an odd number, the difference between the number of first capacitors and the number of second capacitors is preferably made one.

First capacitors 40_1, 40_3, 40_5, and 40_7 are fixed to first fixing plate 50. First fixing plate 50 has a rectangular flat plate shape and is configured to fix a second end portion of a cylindrical portion 44 of first capacitor 40 in the extending direction of cylindrical portion 44. In the example of FIG. 4, first fixing plate 50 is provided with a plurality of receiving jigs 60. Receiving jig 60 has a cylindrical shape and cylindrical portion 44 of capacitor 40 can be arranged therein. By arranging first capacitor 40 in receiving jig 60, first capacitor 40 can be positioned in relation to first fixing plate 50. Thus, first capacitors 40_1, 40_3, 40_5, and 40_7 are arranged side by side in one row so as to stand on first fixing plate 50.

Second capacitors 40_2, 40_4, and 40_6 are fixed to second fixing plate 52. Second fixing plate 52 has a rectangular flat plate shape and is configured to fix a second end portion of a cylindrical portion 44 of second capacitor 40 in the extending direction of cylindrical portion 44. Similarly to first fixing plate 50, second fixing plate 52 is provided with a plurality of receiving jigs 60 for positioning second capacitor 40 in relation to second fixing plate 52. Thus, second capacitors 40_2, 40_4, and 40_6 are arranged side by side in one row so as to stand on second fixing plate 52.

First fixing plate 50 and second fixing plate 52 are connected to second surface 30b of substrate 30. Specifically, first fixing plate 50 is connected to second surface 30b of substrate 30 so as to be orthogonal to second surface 30b of substrate 30 and extend in the Y direction. Thus, cylindrical portions 44 of first capacitors 40_1, 40_3, 40 5, and 40 7 extend in the X direction and are arranged side by side in one row in the Y direction.

Second fixing plate 52 is also connected to second surface 30b of substrate 30 so as to be orthogonal to second surface 30b of substrate 30 and extend in the Y direction. That is, second fixing plate 52 is provided in parallel to first fixing plate 50. Thus, cylindrical portions 44 of second capacitors 40_2, 40_4, and 40_6 extend in the X direction and are arranged side by side in one row in the Y direction.

Further, in the above-described configuration, first fixing plate 50 and second fixing plate 52 are arranged so that their respective surfaces where capacitors 40 are fixed face each other. Accordingly, respective electrode terminals 42P and 42N of second capacitors 40_2, 40_4, and 40_6 are located opposite respective electrode terminals 42P and 42N of first capacitors 40_1, 40_3, 40_5, and 40_7 in the X direction.

In first fixing plate 50, a plurality of (for example, three) through holes 500 for respectively allowing cylindrical portions 44 of second capacitors 40_2, 40_4, and 40_6 to pass therethrough are formed. The plurality of through holes 500 are formed side by side along the Y direction. Through hole 500 corresponds to an example of the “first through hole”.

In second fixing plate 52, a plurality of (for example, four) through holes 520 for respectively allowing cylindrical portions 44 of first capacitors 40_1, 40_3, 40_5, and 40_7 to pass therethrough are formed. The plurality of through holes 520 are formed side by side along the Y direction. Through hole 520 corresponds to an example of the “second through hole”.

First conductive plate 22 constitutes DC line 10. Second conductive plate 24 constitutes DC line 12. First conductive plate 22 and second conductive plate 24 are stacked with interposition of an insulating plate, which is not illustrated. Power conversion device 100 further includes a third conductive plate (not illustrated) constituting AC line 14, and stack 20 is formed by alternately stacking the three conductive plates and the four insulating plates.

First conductive plate 22 includes a base portion 220 and bent portions 222 and 224. Base portion 220 has a shape like a rectangular flat plate, and a plurality of through holes 221 penetrating in the thickness direction are formed in base portion 220. The plurality of through holes 221 are formed by arranging a plurality of sets (for example, six sets) of through holes 221 side by side along the Y direction, where each of the sets is constituted of three through holes 221.

Bent portion 222 is provided on a first end portion of base portion 220 in the X direction and bent perpendicularly to base portion 220. Bent portion 224 is provided on a second end portion of base portion 220 in the X direction and bent perpendicularly to base portion 220. Bent portions 222 and 224 each have a shape of a rectangular flat plate. Base portion 220 corresponds to the “first base portion”, bent portion 222 corresponds to the “first bent portion”, and bent portion 224 corresponds to the “second bent portion”.

A plurality of (for example, four) through holes 223 penetrating bent portion 222 in the thickness direction are formed in bent portion 222. The plurality of through holes 223 are formed side by side along the Y direction. A plurality of (for example, four) through holes 225 penetrating bent portion 224 in the thickness direction are formed in bent portion 224. The plurality of through holes 225 are formed side by side along the Y direction.

Second conductive plate 24 includes a base portion 240 and bent portions 242 and 246. Base portion 240 has the same shape as that of base portion 220 of first conductive plate 22. A plurality of through holes 241 penetrating in the thickness direction are formed in base portion 240. The plurality of through holes 241 are formed by arranging a plurality of sets (for example, six sets) of through holes 241 side by side along the Y direction, where each of the sets is constituted of three through holes 241.

In the state in which first conductive plate 22 and second conductive plate 24 are stacked, through holes 221 formed in base portion 220 of first conductive plate 22 and through holes 241 formed in base portion 240 of second conductive plate 24 overlap each other and are concentrically positioned. Connecting bolts are inserted in the plurality of through holes 221 and 241. By the connecting bolts, DC line 10 can be electrically connected to collector terminals C1 of the plurality of semiconductor modules M1 to M6. In addition, DC line 12 can be electrically connected to emitter terminals E2 of the plurality of semiconductor modules M1 to M6.

Bent portion 242 is provided on a first end portion of base portion 240 in the X direction and bent perpendicularly to base portion 240. Bent portion 246 is provided on a second end portion of base portion 240 in the X direction and bent perpendicularly to base portion 240. Bent portions 242 and 246 each have a shape of a rectangular flat plate. Base portion 240 corresponds to the “second base portion”, bent portion 242 corresponds to the “third bent portion”, and bent portion 246 corresponds to the “fourth bent portion”.

A plurality of through holes 243 and 244 penetrating bent portion 242 in the thickness direction are formed in bent portion 242. The plurality of (for example, four) through holes 243 are formed side by side along the Y direction. The plurality of (for example, four) through holes 244 are formed side by side along the Y direction. Each of through holes 243 and each of through holes 244 are formed side by side in the Z direction.

In the state in which first conductive plate 22 and second conductive plate 24 are stacked, through holes 223 formed in bent portion 222 of first conductive plate 22 and through holes 243 formed in bent portion 242 of second conductive plate 24 overlap each other and are concentrically positioned. Connecting bolts are inserted in the plurality of through holes 223 and 243. By the connecting bolts, DC line 10 can be electrically connected to positive electrode terminals 42P of first capacitors 40_1, 40_3, 40_5, and 40_7. Connecting bolts are inserted in the plurality of through holes 244. By the connecting bolts, DC line 12 can be electrically connected to negative electrode terminals 42N of first capacitors 40_1, 40_3, 40_5, and 40_7.

A plurality of through holes 247 and 248 penetrating bent portion 246 in the thickness direction are formed in bent portion 246. The plurality of (for example, three) through holes 247 are formed side by side along the Y direction. The plurality of (for example, three) through holes 248 are formed side by side along the Y direction. Each of through holes 247 and each of through holes 248 are formed side by side in the Z direction.

In the state in which first conductive plate 22 and second conductive plate 24 are stacked, through holes 225 formed in bent portion 224 of first conductive plate 22 and through holes 247 formed in bent portion 246 of second conductive plate 24 overlap each other and are concentrically positioned. Connecting bolts are inserted in the plurality of through holes 225 and 247. By the connecting bolts, DC line 10 can be electrically connected to positive electrode terminals 42P of second capacitors 40_2, 40_4, and 40_6. Connecting bolts are inserted in the plurality of through holes 248. By the connecting bolts, DC line 12 can be electrically connected to negative electrode terminals 42N of second capacitors 40_2, 40_4, and 40_6.

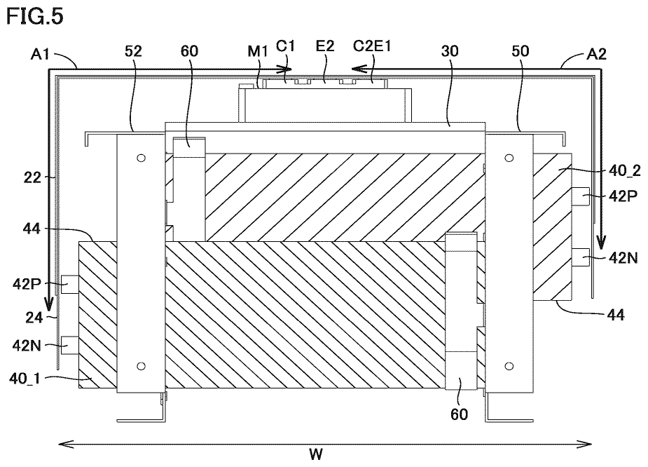

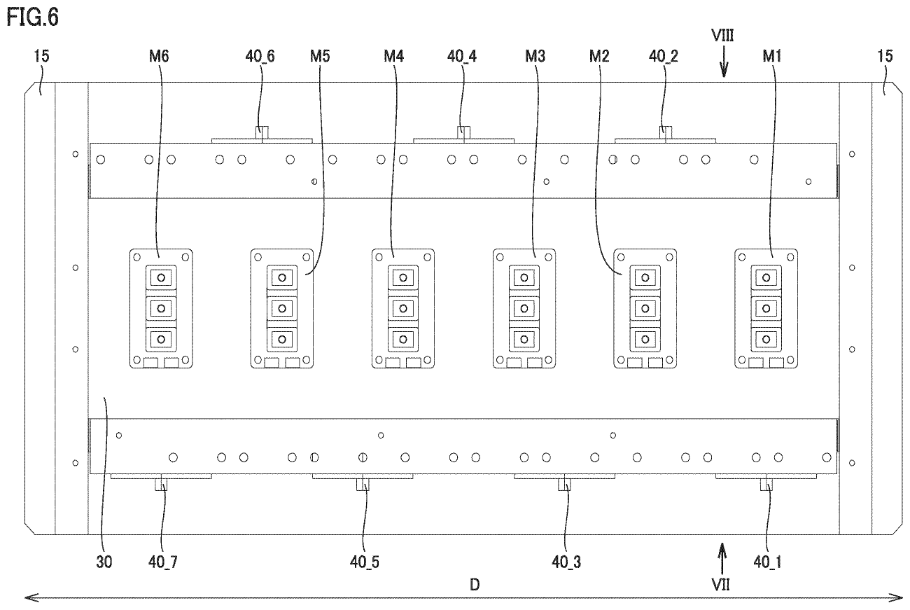

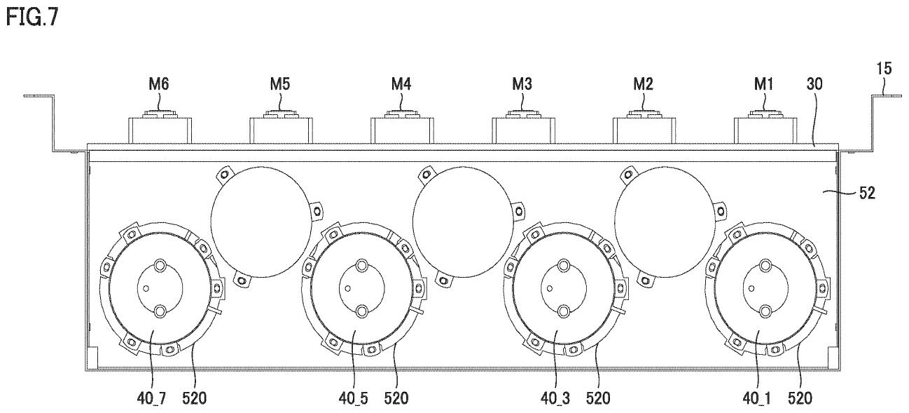

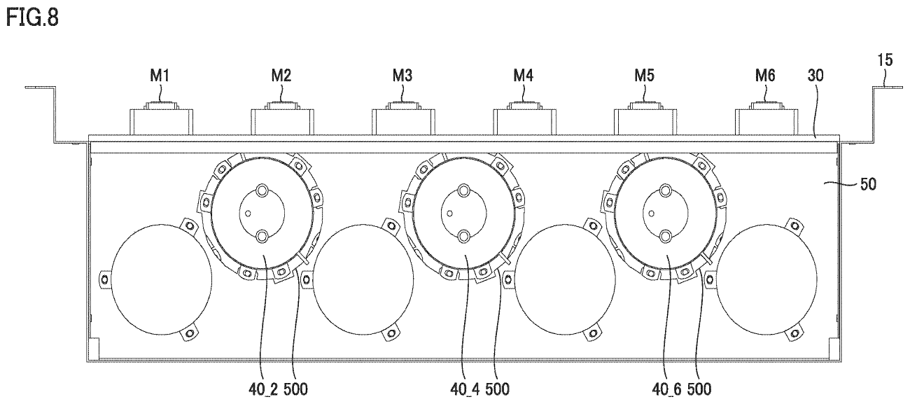

FIG. 5 is a front view of power conversion device 100. FIG. 6 is a top view of power conversion device 100. FIG. 7 is a side view of power conversion device 100 seen in the direction of arrow VII shown in FIG. 6. FIG. 8 is a side view of power conversion device 100 seen in the direction of arrow VIII shown in FIG. 6. In FIG. 5, housing 15 is not illustrated. In FIG. 6, housing 15 and stack 20 are not illustrated.

As illustrated in FIG. 5, power conversion device 100 is configured by, above first fixing plate 50 fixing first capacitors 40_1, 40_3, 40_5, and 40_7 and second fixing plate 52 fixing second capacitors 40_2, 40_4, and 40_6 in the Z direction, stacking substrate 30 on which the plurality of semiconductor modules M are mounted and stack 20 including first conductive plate 22 and second conductive plate 24.

First fixing plate 50 and second fixing plate 52 are arranged so that their respective surfaces where capacitors 40 are fixed face each other. As illustrated in FIG. 7, first capacitors 40_1, 40_3, 40_5, and 40_7 are arranged side by side in one row in the Y direction. As illustrated in FIG. 8, second capacitors 40_2, 40_4, and 40_6 are arranged side by side in one row in the Y direction. As illustrated in FIGS. 5 and 6, respective electrode terminals 42P and 42N of second capacitors 40_2, 40_4, and 40_6 are located opposite respective electrode terminals 42P and 42N of first capacitors 40_1, 40_3, _5, and 40_7 in the X direction.

Positive electrode terminal 42P of first capacitor 40 is connected to bent portion 222 of first conductive plate 22 by the connecting bolts inserted in through holes 223 and 243 (FIG. 4). Negative electrode terminal 42N of first capacitor 40 is connected to bent portion 242 of second conductive plate 24 by the connecting bolt inserted in through hole 244 (FIG. 4).

Positive electrode terminal 42P of second capacitor 40 is connected to bent portion 224 of first conductive plate 22 by the connecting bolts inserted in through holes 225 and 247. Negative electrode terminal 42N of second capacitor 40 is connected to bent portion 246 of second conductive plate 24 by the connecting bolt inserted in through hole 248.

Collector terminal C1 of semiconductor module M is connected to base portion 220 of first conductive plate 22 by the connecting bolts inserted in through holes 221 and 241. Emitter terminal E2 of semiconductor module M is connected to base portion 240 of second conductive plate 24 by the connecting bolt inserted in through hole 241.

As illustrated in FIG. 5, in a plan view seen in the Y direction, first capacitor 40 and second capacitor 40 are arranged so that their respective cylindrical portions 44 partially overlap each other in the X direction. Further, first capacitor 40 and second capacitor 40 are arranged so that their respective cylindrical portions 44 partially overlap each other in the Z direction.

When first capacitor 40 and second capacitor 40 are arranged side by side along the X direction so that the second end portions of cylindrical portions 44 face each other, a dimension W of power conversion device 100 in the X direction is approximately twice the length of cylindrical portion 44 of capacitor 40. In contrast, in the present embodiment, the dimension W of power conversion device 100 in the X direction can be shortened by first capacitor 40 and second capacitor 40 being arranged so as to partially overlap each other in the X direction.

On the other hand, when first capacitor 40 and second capacitor 40 are alternately arranged side by side in one row in the Y direction, a dimension D of power conversion device 100 in the Y direction is the length based on the product of the diameter of cylindrical portion 44 of capacitor 40 and the number of capacitors 40. Accordingly, depending on the number of capacitors 40 constituting capacitor circuit 16, an increase in the area occupied by power conversion device 100 may be caused.

In the present embodiment, the plurality of capacitors 40 are arranged in a staggered manner along the Y direction as illustrated in FIGS. 7 and 8 by arranging first capacitor 40 and second capacitor 40 so that their respective cylindrical portions 44 partially overlap each other in the Z direction. That is, the plurality of capacitors 40 are arranged at equal intervals in two rows in the Y direction and are alternately arranged in the opposite rows. Accordingly, the interval between first capacitors 40 adjacent to each other in the Y direction and the interval between second capacitors 40 adjacent to each other in the Y direction can be narrowed. Thus, it is enabled to shorten the dimension W in the X direction and the dimension D in the Y direction of power conversion device 100 and decrease the area occupied by power conversion device 100.

Further, by arranging first capacitor 40 and second capacitor 40 so that their respective cylindrical portions 44 partially overlap in the Z direction, it is enabled to decrease the difference between the positions of electrode terminals 42P and 42N of first capacitor 40 in the Z direction and the positions of electrode terminals 42P and 42N of second capacitor 40 in the Z direction.

Arrow A1 in FIG. 5 indicates a distance between first capacitor 40 and semiconductor module M. Arrow A2 in FIG. 5 indicates a distance between second capacitor 40 and semiconductor module M. By suitably setting the positions of first capacitor 40 and second capacitor 40 in the Z direction and the position of semiconductor module M in the X direction, it is enabled to eliminate variation in the distance between semiconductor module M and first capacitor 40 and the distance between semiconductor module M and second capacitor 40. Thus, according to the present embodiment, it is enabled, without increasing the area occupied by power conversion device 100, to solve the problem that variation in the inductance of a current path may be caused among the plurality of capacitors 40.

It should be understood that the herein-disclosed embodiments are presented by way of illustration and example in all respects and are not to be taken by way of limitation. The scope of the present disclosure is defined by the claims rather than by the foregoing description and intended to include any modifications within the purport and scope equivalent to the claims.

### REFERENCE SIGNS LIST

5 controller; 10, 12 DC line; 14 AC line; 15, 215 housing; 16 capacitor circuit; 20, 210 stack; 22 first conductive plate; 24 second conductive plate; 30, 230 substrate; 40 capacitor; 42P positive electrode terminal; 42N negative electrode terminal; 44 cylindrical portion; 50 first fixing plate; 52 second fixing plate; 60 receiving jig; 100, 200 power conversion device; 220, 240 base portion; 222, 224, 242, 246 bent portion; 221, 223, 225, 243, 244, 247, 248, 500, 520 through hole; M, M1-M6 semiconductor module; C1 collector terminal; E2 emitter terminal; C2E1 collector-emitter terminal; G1, G2, E1, E2 control terminal; Q1, Q2 semiconductor switching element; D1, D2 diode; AC1, AC2 AC terminal; BP1, BP2 positive electrode DC terminal; BN1, BN2 negative electrode DC terminal.

1. A power conversion device comprising:
a plurality of capacitors electrically connected in parallel;
a plurality of semiconductor modules electrically connected to the plurality of capacitors; and
a substrate including a first surface on which the plurality of semiconductor modules are mounted, and a second surface being opposite the first surface, wherein
the plurality of semiconductor modules are arranged on the first surface of the substrate so as to be aligned along a first direction orthogonal to a vertical direction of the power conversion device,
each of the plurality of capacitors includes a cylindrical portion, and first and second electrode terminals arranged in a first end portion of the cylindrical portion in an extending direction of the cylindrical portion,
the plurality of capacitors include at least one first capacitor and at least one second capacitor,
the at least one first capacitor is arranged on a side of the second surface of the substrate so that the extending direction of the cylindrical portion is a second direction orthogonal to the vertical direction and the first direction,
the at least one second capacitor is arranged on the side of the second surface of the substrate so that the extending direction of the cylindrical portion is the second direction and the first and second electrode terminals of the at least one second capacitor are located opposite the first and second electrode terminals of the at least one first capacitor in the second direction, and
in a plan view seen in the first direction, the at least one first capacitor and the at least one second capacitor are arranged so that the cylindrical portions of the at least one first capacitor and the at least one second capacitor partially overlap each other in the vertical direction and the second direction.

2. The power conversion device according to claim 1, wherein
the at least one first capacitor includes a plurality of first capacitors,
the at least one second capacitor includes a plurality of second capacitors,
in a plan view seen in the second direction, the plurality of first capacitors and the plurality of second capacitors are arranged in a staggered manner in the first direction, and
in a plan view seen in the first direction, the first capacitor and the second capacitor adjacent to each other in the second direction are arranged so that the cylindrical portions of the first capacitor and the second capacitor partially overlap each other in the vertical direction and the second direction.

3. The power conversion device according to claim 1, wherein
each of the plurality of semiconductor modules includes a first main electrode terminal and a second main electrode terminal,
the power conversion device further comprises:
a first conductive plate; and
a second conductive plate, the first conductive plate and the second conductive plate being stacked with interposition of an insulating plate,
the first conductive plate includes
a first base portion facing the first surface of the substrate, the first main electrode terminals of the plurality of semiconductor modules being connected to the first base portion,
a first bent portion bent in the vertical direction from a first end portion of the first base portion in the second direction, the first electrode terminal of the at least one first capacitor being electrically connected to the first bent portion, and
a second bent portion bent in the vertical direction from a second end portion of the first base portion in the second direction, the first electrode terminal of the at least one second capacitor being electrically connected to the second bent portion,
the second conductive plate includes
a second base portion lying under the first base portion, the second main electrode terminals of the plurality of semiconductor modules being connected to the second base portion,
a third bent portion bent in the vertical direction from a first end portion of the second base portion in the second direction, the second electrode terminal of the at least one first capacitor being electrically connected to the third bent portion, and
a fourth bent portion bent in the vertical direction from a second end portion of the second base portion in the second direction, the second electrode terminal of the at least one second capacitor being electrically connected to the fourth bent portion.

4. The power conversion device according to claim 3, wherein
a plurality of through holes are formed in the first base portion along the first direction,
a plurality of through holes are formed in the second base portion to overlap the through holes formed in the first base portion, and
the through hole formed in the first base portion and the through hole formed in the second base portion are provided so as to allow a bolt to be inserted through the through holes.

5. The power conversion device according to claim 3, wherein
a plurality of through holes are formed in the first bent portion along the first direction,
a plurality of through holes are formed in the third bent portion to overlap the through holes formed in the first bent portion, and
the through hole formed in the first bent portion and the through hole formed in the third bent portion are provided so as to allow a bolt to be inserted through the through holes.

6. The power conversion device according to claim 3, wherein
a plurality of through holes are formed in the second bent portion along the first direction,
a plurality of through holes are formed in the fourth bent portion to overlap the through holes formed in the second bent portion, and
the through hole formed in the second bent portion and the through hole formed in the fourth bent portion are provided so as to allow a bolt to be inserted through the through holes.

7. The power conversion device according to claim 1, further comprising:
a first fixing plate connected to the second surface of the substrate in the vertical direction and extending in the first direction; and
a second fixing plate connected to the second surface of the substrate in the vertical direction and provided in parallel to the first fixing plate, wherein
the first fixing plate fixes a second end portion of the cylindrical portion of the at least one first capacitor in the extending direction of the cylindrical portion,
the second fixing plate fixes a second end portion of the cylindrical portion of the at least one second capacitor in the extending direction of the cylindrical portion,
at least one first through hole for allowing the cylindrical portion of the at least one second capacitor to pass through the at least one first through hole is formed in the first fixing plate, and
at least one second through hole for allowing the cylindrical portion of the at least one first capacitor to pass through the at least one second through hole is formed in the second fixing plate.

8. The power conversion device according to claim 2, wherein
each of the plurality of semiconductor modules includes a first main electrode terminal and a second main electrode terminal,
the power conversion device further comprises:
a first conductive plate; and
a second conductive plate, the first conductive plate and the second conductive plate being stacked with interposition of an insulating plate,
the first conductive plate includes
a first base portion facing the first surface of the substrate, the first main electrode terminals of the plurality of semiconductor modules being connected to the first base portion,
a first bent portion bent in the vertical direction from a first end portion of the first base portion in the second direction, the first electrode terminal of the at least one first capacitor being electrically connected to the first bent portion, and
a second bent portion bent in the vertical direction from a second end portion of the first base portion in the second direction, the first electrode terminal of the at least one second capacitor being electrically connected to the second bent portion,
the second conductive plate includes
a second base portion lying under the first base portion, the second main electrode terminals of the plurality of semiconductor modules being connected to the second base portion,
a third bent portion bent in the vertical direction from a first end portion of the second base portion in the second direction, the second electrode terminal of the at least one first capacitor being electrically connected to the third bent portion, and
a fourth bent portion bent in the vertical direction from a second end portion of the second base portion in the second direction, the second electrode terminal of the at least one second capacitor being electrically connected to the fourth bent portion.

9. The power conversion device according to claim 8, wherein
a plurality of through holes are formed in the first base portion along the first direction,
a plurality of through holes are formed in the second base portion to overlap the through holes formed in the first base portion, and
the through hole formed in the first base portion and the through hole formed in the second base portion are provided so as to allow a bolt to be inserted through the through holes.

10. The power conversion device according to claim 8, wherein
a plurality of through holes are formed in the first bent portion along the first direction,
a plurality of through holes are formed in the third bent portion to overlap the through holes formed in the first bent portion, and
the through hole formed in the first bent portion and the through hole formed in the third bent portion are provided so as to allow a bolt to be inserted through the through holes.

11. The power conversion device according to claim 8, wherein
a plurality of through holes are formed in the second bent portion along the first direction,
a plurality of through holes are formed in the fourth bent portion to overlap the through holes formed in the second bent portion, and
the through hole formed in the second bent portion and the through hole formed in the fourth bent portion are provided so as to allow a bolt to be inserted through the through holes.

12. The power conversion device according to claim 2, further comprising:
a first fixing plate connected to the second surface of the substrate in the vertical direction and extending in the first direction; and
a second fixing plate connected to the second surface of the substrate in the vertical direction and provided in parallel to the first fixing plate, wherein
the first fixing plate fixes a second end portion of the cylindrical portion of the at least one first capacitor in the extending direction of the cylindrical portion,
the second fixing plate fixes a second end portion of the cylindrical portion of the at least one second capacitor in the extending direction of the cylindrical portion,
at least one first through hole for allowing the cylindrical portion of the at least one second capacitor to pass through the at least one first through hole is formed in the first fixing plate, and
at least one second through hole for allowing the cylindrical portion of the at least one first capacitor to pass through the at least one second through hole is formed in the second fixing plate.
